(19) United States
(12) Patent Application Publication
(10) Pub. No.: US 2019/0157564 A1
(43) Pub. Date: May 23, 2019

(54) METHOD FOR OLED DEVICE FABRICATION USING PATTERNED FILM MASK

(71) Applicant: SABIC Global Technologies B.V., Bergen op Zoom (NL)

(72) Inventors: Sang Hoon KIM, Seoul (KR); Byungwan LIM, Seoul (KR)

(21) Appl. No.: 15/773,865

(22) PCT Filed: Nov. 4, 2016
(86) PCT No.: PCT/IB2016/056646

§ 371 Date: May 4, 2018

Related U.S. Application Data
(60) Provisional application No. 62/251,830, filed on Nov. 6, 2015.

(51) Int. Cl. H01L 51/00; H01L 51/56; H01L 51/50; H01L 51/52

(52) U.S. Cl. CPC H01L 51/0016; H01L 51/56; H01L 51/0003; H01L 51/0021; H01L 2251/5338; H01L 51/5012; H01L 51/5206; H01L 51/5221; H01L 2251/301; H01L 51/0097

(57) ABSTRACT

A patterned film mask for applying a film layer to a substrate is disclosed. The patterned film mask includes a base layer and a plurality of through holes. The plurality of through holes permeates through the base layer and defines a predetermined pattern for the film layer. The film layer and the base layer have at least one different surface wettability characteristic and the substrate and the film layer have at least one of the same wettability characteristics. Specifically, the substrate and the film layer may be hydrophilic while the base layer may be hydrophobic. Alternatively, the substrate and the film layer may be hydrophobic while the base layer may be hydrophilic.

### TECHNICAL FIELD

The present disclosure relates to a patterned film mask for thin film deposition and more particularly, to a process of fabricating an organic light-emitting device using the same.

### BACKGROUND

Today, organic light emitting diodes (OLEDs) are increasingly used in lighting applications because they are more energy efficient than other conventional lighting sources. OLEDs typically have a stacked structure composed of one or more organic layers positioned between two electrodes. At least one of the two electrodes, either the anode or the cathode electrode is formed from a transparent conductive material, which enables the light emitted from the OLED to be visible.

The transparent conductive material used as electrode should possess certain properties such as low resistivity and high optical transmittance to produce an OLED device with desirable performance. Indium tin oxide (ITO) is a transparent electrode material that is useful in OLED applications due to its high transparency in the visible wavelength range. For example, ITO is commonly used in many liquid crystal display LCD applications. Transparent conductive oxides, such as ITO, however, are problematic for flexible OLED devices because they are brittle and prone to cracking under stress. Furthermore, the cracking reduces the conductivity of the electrode and ultimately may degrade the OLED. This particular drawback has limited the use of ITO in flexible OLEDs. As a result, alternative materials to ITO such as silver nanowires or other metal nanowires, metal nanoparticles, carbon nanotubes, PEDOT:PSS, and graphene are often used for flexible OLED applications. These materials possess advantageous properties such as strong adhesion with the substrate, wettability, and high glass transition temperatures that make them desirable as electrode materials.

These alternative materials have been applied to flexible plastic substrates using vacuum and non-vacuum processes. Although, vacuum processes have produced electrodes with favorable performance characteristics, the vacuum processes tend to be expensive, complex, and take place at extremely high process temperatures, making them less desirable than the non-vacuum processes for electrode formation.

In non-vacuum processes, the electrode material is initially coated on the surface of the plastic flexible substrate. After coating the electrode on the substrate, photolithography or laser patterning methods are used to pattern the electrode. These patterning methods are complicated processes and place limitations on the types of substrates that may be used when forming an OLED device. Certain processes such as laser irradiation patterning tend to damage the underlying layer or the plastic substrate during patterning. Furthermore, the etching solution used in these patterning methods poses environmental concerns.

Therefore, there is a need for improved OLEDs and processes for forming OLEDs. There is also a need for improved methods of applying thin film materials to substrates. Accordingly, the disclosed patterned film mask and processes are directed at overcoming one or more of these disadvantages in currently available OLEDs.

### SUMMARY

In accordance with one aspect of the disclosure, a patterned film mask for applying a film layer to a substrate is disclosed. The patterned film mask includes a base layer and a plurality of through holes that permeate through the base layer. The plurality of through holes defines a predetermined pattern for the film layer that is applied to the substrate. The film layer and the base layer have at least one different surface wettability characteristic and the substrate and the film layer have at least one surface wettability characteristic that is the same.

In accordance with one aspect of the disclosure, a process of fabricating a patterned film layer on a substrate is disclosed. The process includes providing a patterned film mask, wherein the patterned film mask comprises a base layer and a plurality of through holes permeating through the base layer. The plurality of through holes defines a predetermined pattern for the patterned film layer that is applied to the substrate. The film layer and the base layer have at least one different surface wettability characteristics and the substrate and the film layer have at least one surface wettability characteristic that is the same. The process further includes positioning the patterned film mask over the substrate, depositing a film layer material on the substrate and into the plurality of through holes, and removing the patterned film mask from the substrate.

In accordance with yet another aspect of the disclosure, a patterned film mask for applying a film layer to a substrate is disclosed. The patterned film mask includes a base layer and a plurality of through holes that permeate through the base layer. The plurality of through holes defines a predetermined pattern for the film layer that is applied to the substrate. The substrate and the film layer may be hydrophilic and the base layer may be hydrophobic.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a cross-sectional view of the patterned film mask according to one aspect of the present disclosure.

FIG. 2 is a schematic illustration of the spray coating process using the patterned film mask according to one aspect of the present disclosure.

FIG. 3 is a schematic illustration of fabricating a multi-stacked patterned film mask according to one aspect of the present disclosure.

FIG. 4 is a schematic illustration of the surface treatment of the patterned film mask according to one aspect of the present disclosure.

### DETAILED DESCRIPTION

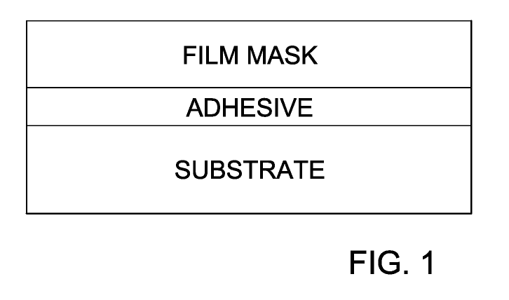

The present disclosure provides a patterned film mask for use in applying a thin film layer to a substrate. FIG. 1 illustrates a cross section of the patterned film mask adhered to a substrate. According to one aspect of the disclosure, the patterned film mask is useful in fabricating organic light-emitting diodes (OLEDs). The OLEDs disclosed herein may in some aspects of the disclosure be particularly useful for flexible OLED applications or structures in which an OLED is provided on a flexible lightweight substrate. For example, flexible lightweight substrates may be plastic (e.g. polymer) substrates or flexible metal foils as opposed to rigid glass substrates. The disclosure, however, is not limited to flexible OLED structures and the processes disclosed herein may be used to form a wide variety of OLED structures and non-OLED structures.

Substrate

The patterned film mask may be used to form a patterned film layer on a substrate. The patterned film mask disclosed herein may apply thin film layers on many different types of substrates and the disclosure is not limited in this regard. The substrate is generally configured to provide support for the OLED. In some aspects, the substrate may be transparent allowing light generated by the OLED to pass through the OLED.

The substrate may comprise any suitable material known in the art. Suitable substrate materials may include, but are not limited to, glass, plastics, semiconductor materials such as silicon, and ceramics. Specific examples of the substrate may include, but are not limited to a plate or a foil of metal such as aluminum (including aluminum alloy), zinc, copper and iron; a film made of plastic such as cellulose acetate, polyethylene terephthalate (PET), polyethylene naphthalate (PEN), polyethylene, polyester, polyamide, polyimide, polystyrene, polypropylene, polycarbonate, polyvinyl acetal, aramid and polyphenylene sulfide; and paper having plastic (polyethylene, polypropylene, polystyrene, or the like) laminated thereon or paper coated with plastic (polyethylene, polypropylene, polystyrene, or the like), paper or a plastic film having the above-mentioned metal laminated thereon or vapor-deposited thereon.

The thickness of the substrate is not particularly limited. For OLED devices, particularly flexible OLED devices, the substrate thickness may be 300 μm or less, more preferably 200 μm or less, and even more preferably 100 μm or less. In some aspects of the disclosure, the substrate thickness may range from 10 μm to 50 μm.

In some aspects of the disclosure, the substrate may be hydrophilic. In other aspects of the disclosure, the substrate may be hydrophobic. The substrate surface may be treated with a hydrophilic or hydrophobic treatment as appropriate. The substrate should have at least one different surface wettability characteristic than the base layer. In some aspects, either one of the substrate or the film layer should demonstrate a stronger tendency toward hydrophobicity, while the other demonstrates a stronger tendency towards hydrophilicity. The substrate, however, should have at least one of the same surface wettability characteristics as the film layer. For example, if the film layer material is hydrophobic, then the substrate may also be hydrophobic. If the film layer material is hydrophilic, then the substrate may also be hydrophilic.

Patterned Film Layer

In some aspects of the disclosure, the patterned film layer (also referred to herein as the film layer) produced may function as an electrode (e.g. anode or cathode) in an OLED. The patterned film layer produced herein may also function as an insulating layer or an organic emission layer in an OLED. As set forth above, a typical OLED includes an anode and a cathode with at least one organic layer disposed between the anode and cathode. The anode or cathode or both may be a thin metal material. In some aspects, the anode and/or cathode material may be a transparent or substantially transparent conductive material. In one aspect, the anode and/or cathode material may be a transparent or substantially transparent metal. For example, the anode or cathode material may be indium-tin oxide (ITO), indium-zinc oxide (IZO) and tin oxide. However, for flexible OLEDs other metal oxides are preferred including, but not limited to, silver, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used.

In some aspects, gold, iridium, molybdenum, palladium, and platinum may be useful as electrode materials if the electrode is not required to be transparent. These film layer materials may be deposited by any suitable means such as spray coating, evaporation, sputtering, chemical vapor deposition, or electrochemical means. In some aspects, application of the film layer material may occur at room temperature and atmospheric pressure.

In some aspects of the disclosure, the film layer may be hydrophilic. In other aspects of the disclosure, the film layer may be hydrophobic. The film layer may have at least one different surface wettability characteristic as the base layer. In other words, one of the film layer or base layer may demonstrate a stronger tendency toward hydrophobicity, while the other demonstrates a stronger tendency towards hydrophilicity. The film layer and the substrate, however, may have at least one of the same surface wettability characteristics. For example, if the film layer material is hydrophobic, then the substrate may also be hydrophobic. If the film layer material is hydrophilic, then the substrate may be hydrophilic.

Through Holes

The patterned film mask is used for depositing a film layer material in a predetermined pattern on a substrate. In some aspects of the present disclosure, a plurality of film layers in a desired pattern may be formed on a predetermined position of the substrate at a time using the patterned film mask.

According to one aspect of the present disclosure, the patterned film mask includes a base layer and a plurality of through holes permeating through the base layer. In order to deposit the film layer material in the desired pattern, the film mask includes a plurality of through holes through which the film layer material passes to form the patterned film layer. The through holes should permeate from one surface of the base layer to the opposing surface of the base layer. For example, the through holes permeate from the bottom surface of the base layer to the top surface of the base layer. The through holes permit the film layer material to be deposited onto the surface of the substrate. In one aspect of the disclosure, the through holes are formed by a laser scribing process or a punching process. Other processes, however, are contemplated by the present disclosure.

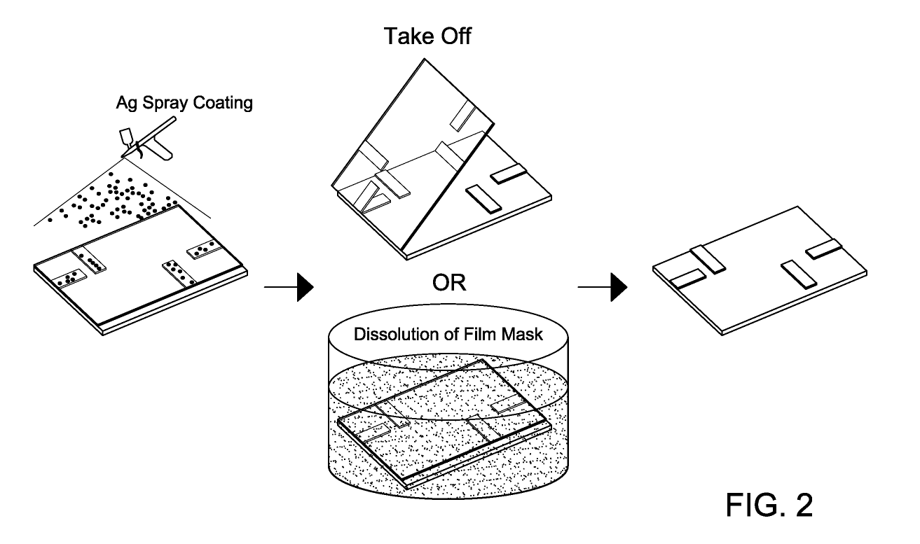

The through holes in the base layer correspond to the desired pattern for the film layer on the substrate. The number of through holes and the dimensions of the through holes are a design choice and represent the desired features for the film layer. In some aspects of the present disclosure, the through holes may have different shapes and sizes from each other within the same film mask. In some aspects, the through holes may be circular perforations in the base layer. In other aspects, the through holes are formed in the shape of a rectangle as shown in FIGS. 2-4. According to other aspects of the disclosure, the through holes may have shapes that are neither circular nor rectangular.

Base Layer

In one aspect of the present disclosure, the base layer of the patterned film mask is dissolvable in an aqueous media. For example, in one aspect the base layer is composed of a material that is soluble in water and particularly deionized water. In one embodiment, the water-soluble base layer may be composed of materials including, but not limited to, polyvinyl alcohol, polyacrylic acid, dextran, polymethacrylic acid, polyethylene imine, or polyethylene oxide. In other aspects of the present disclosure, the base layer may be composed of a material that is soluble in alkaline solution or an acidic solution, provided that the underlying substrate and the film layer applied to the substrate are not compromised by these solutions. Those skilled in the art will recognize that an advantage of the base layer being dissolvable in an aqueous media is that the patterned film mask can be easily removed from the substrate while leaving the film layer intact without leaving any residue on the substrate.

The base layer may be composed of a resin material suitable for forming the patterned film mask. Accordingly, any resin material may be employed as the base layer as long as it allows for the formation of through holes that permeate through the base layer. Specific examples of the resin material include a silicone resin, an epoxy resin, a polyallylate resin, a PET modified polyallylate resin, a polycarbonate resin (PC), cyclic olefin, a polyethylene terephthalate resin (PET), a polymethylmethacrylate resin (PMMA), a polypropylene resin (PP), modified acryl resin, a polystyrene resin (PE), and an acrylonitrile-styrene copolymer resin (AS).

In some aspects of the disclosure, the base layer may be hydrophilic. In other aspects of the disclosure, the base layer may be hydrophobic. The base layer may be treated with a hydrophilic or hydrophobic treatment as appropriate.

The base layer may have at least one different surface wettability characteristics than the substrate. In other words, one of the base layer or substrate may demonstrate a stronger tendency toward hydrophobicity, while the other demonstrates a stronger tendency towards hydrophilicity. The base layer may also have different surface wettability characteristics than the film layer. For example, if the film layer material is hydrophobic, then the base layer may be hydrophilic. If the film layer material is hydrophilic, then the base layer may be hydrophobic.

Adhesive Layer

The patterned film mask may also include an adhesive layer disposed on the base layer. The adhesive layer is configured to adhere the base layer of the patterned film mask to the substrate. FIG. 1 illustrates a cross section of the patterned film mask adhered to a substrate, including an adhesive layer. The through holes in the patterned film mask are not shown in FIG. 1 for simplification of the illustration. Example materials for the adhesive layer may include, but are not limited to, silicone, acrylic or urethane based adhesives. The adhesive layer may be an adhesive coating applied to the base layer or an adhesive film layer applied to the substrate. The application of the adhesive layer should not interfere with the plurality of through holes such that the film layer material may properly flow through the through holes in forming the film layer. In some aspects of the present disclosure, the adhesive layer may be applied to the base layer prior to forming the through holes. For example, the patterned film mask may be formed by providing the base layer, applying the adhesive material or adhesive layer to the base layer. Once the adhesive layer is applied, the through holes may be formed such that the through holes permeate through both the base layer and the adhesive layer.

Referring to FIG. 2, a process for applying a patterned electrode to a substrate is shown. As shown, the patterned film mask is initially adhered to the substrate. Silver, the film layer material, is deposited on the substrate through the through holes in the film mask by a spray coating method. The spray coating method may be performed at room temperature and at atmospheric pressure. Although not shown in FIG. 2, the film mask and the substrate may be dried after the spray coating is completed. The drying step may occur at room temperature.

Once the silver has been deposited on the substrate, the film mask is removed from the substrate. The removal of the film mask from the substrate may occur by physically separating the film mask from the substrate. Alternatively, the film mask may be dissolved in an aqueous solution as shown in FIG. 2. The film mask may be placed in a bath of the aqueous solution for a period of time until the base layer and adhesive layer (if present) no longer remain on the substrate. After removal of the film mask from the substrate, the patterned film layer or electrode remains on the substrate.

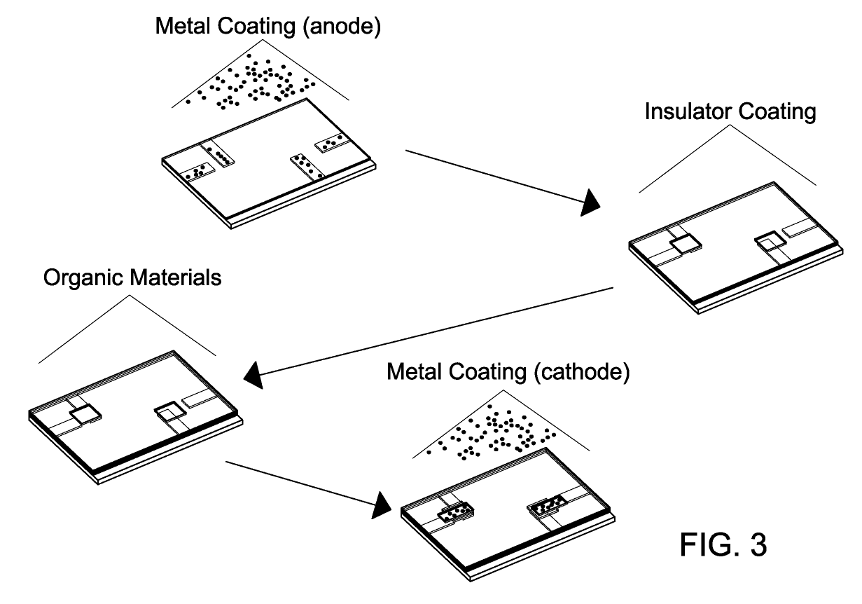

Referring now to FIG. 3, an OLED is fabricated using different film masks to form the various layers including anode, insulator layer, organic layer, and cathode. In step 1, a first patterned film mask (1) is adhered to the substrate and a metal anode coating is deposited on the film mask (1) to form a patterned anode on the substrate. In step 2, a second patterned film mask (2) is superimposed on the anode and an insulator coating material is deposited on the film mask (2) to form an insulting layer over the anode. In step 3, a third patterned film mask is superimposed on the insulator layer and an organic material is deposited on the film mask (3) to form an organic layer on the insulator layer. In step 4, a fourth patterned film mask (4) is superimposed on the organic layer and a metal coating is deposited on the film mask (4) to form a cathode on the organic layer.

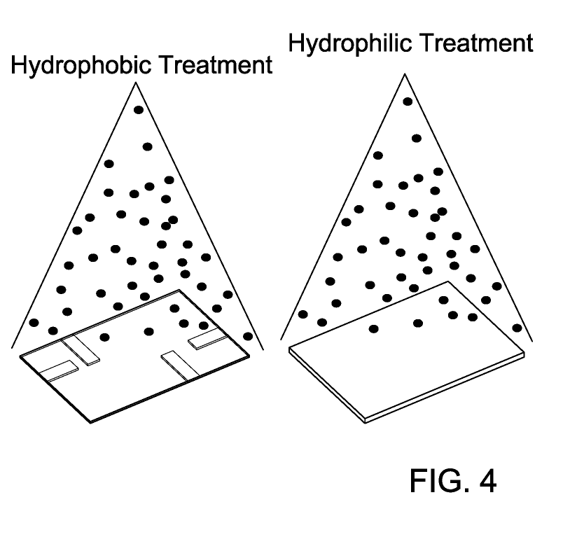

Referring now to FIG. 4, a patterned film mask undergoing hydrophobic treatment is shown. This hydrophobic treatment will render the surface of the patterned film mask hydrophobic. The substrate shown in FIG. 4 receives a hydrophilic treatment, which renders the surface of the substrate hydrophilic. Depending on the wettability characteristics of the film layer material used, it may be advantageous to perform a hydrophobic surface treatment on the patterned film mask and a hydrophilic surface treatment on the substrate, respectively. Alternatively, a hydrophilic surface treatment may be performed on the patterned film mask and a hydrophobic surface treatment on the substrate.

An important feature of the present disclosure is the surface wettability characteristics of the base layer of the film mask, the film layer or film layer material and the substrate. The film layer and the substrate having the same surface wettability characteristics ensure proper deposition of the film material on the substrate. The base layer and the substrate having different surface wettability characteristics ensure that the film mask properly adheres to the substrate without any gaps. This difference in surface wettability characteristics also safeguards that the film material adheres to the substrate and not the patterned film mask. Therefore, greater pattern accuracy may be achieved.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

### Definitions

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “light” means electromagnetic radiation including ultraviolet, visible or infrared radiation.

As used herein, the term “hydrophobic” refers to materials that repel, tend not to combine with, or are incapable of dissolving in water. Characteristics of hydrophobic materials are high contact angle with a water droplet, poor adhesiveness, poor wettability characteristics, and low solid surface free energy. For example, in one aspect, a hydrophobic material may have a water contact angle that is greater than 90 degrees.

As used herein, the term “hydrophilic” refers to materials that have an affinity for water and are readily absorbed or dissolved in water. Hydrophilic materials generally have polar or charged functional groups rendering them soluble in water. Characteristics of hydrophilic materials are low surface contact angle, good wettability, good adhesiveness and high solid surface free energy. For example, in one aspect, a hydrophilic material may have a water contact angle that is less than 90 degrees.

As used herein, the term “surface wettability characteristic” refers to the degree of a surface's wettability and may include a highly wettable surface, a highly non-wettable surface or any variation of wettability in between. Examples of surface wettability characteristics may include, but are not limited to, properties such as surface tension, surface free energy, viscosity, polarity, hydrophilicity or, hydrophobicity and the water contact angle of the surface. In one aspect, articles having at least one different surface wettability characteristic may refer to one surface being hydrophobic or having a water contact angle that is greater than 90 degrees and the other surface as being hydrophilic or having a water contact angle that is less than 90 degrees. In another aspect, articles or fluids having at least one of the same surface wetting characteristics may refer to two different surfaces that are both hydrophobic or both hydrophilic.

As used herein, the term “transparent” means that the level of transmittance for a disclosed composition is greater than 50%. In some embodiments, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

Unless otherwise stated to the contrary herein, all test standards are the most recent standard in effect at the time of filing this application.

Aspects

The present disclosure comprises at least the following aspects.

Aspect 1. A patterned film mask for applying a film layer to a substrate, the patterned film mask comprising: a base layer; and a plurality of through holes permeating through the base layer, wherein the plurality of through holes defines a predetermined pattern for the film layer applied to the substrate.

Aspect 2. The patterned film mask of aspect 1, wherein the film layer and the base layer have at least one different surface wettability characteristic and the substrate has at least one of the same surface wettability characteristics as the film layer.

Aspect 3. The patterned film mask of aspect 2, wherein the base layer is hydrophobic and the substrate and the film layer are hydrophilic.

Aspect 4. The patterned film mask of aspect 2, wherein the base layer is hydrophilic and the substrate and the film layer are hydrophobic.

Aspect 5. The patterned film mask of aspect 1, wherein the plurality of through holes is formed by a laser scribing process.

Aspect 6. The patterned film mask of aspect 1, wherein the plurality of through holes is formed by a punching process.

Aspect 7. The patterned film mask of the preceding aspects, wherein the film layer is an electrode used in an organic light-emitting diode.

Aspect 8. The patterned film mask of the preceding aspects, wherein the film layer is an insulating layer in an organic light emitting diode.

Aspect 9. The patterned film mask of the preceding aspects, wherein the film layer is an organic emission layer in an organic light emitting diode.

Aspect 10. The patterned film mask of the preceding aspects, wherein the base layer comprises a polymeric material.

Aspect 11. The patterned film mask of the preceding aspects, wherein the base layer comprises a water-soluble polymeric material.

Aspect 12. The patterned film mask of the preceding aspects, wherein the base layer comprises polyvinyl alcohol.

Aspect 13. The patterned film mask of the preceding aspects, further comprising a hydrophobic layer disposed on the surface of the base layer, wherein the plurality of through holes permeate through the hydrophobic layer and the base layer.

Aspect 14. The patterned film mask of aspect 13, wherein the substrate comprises a hydrophilic material or the surface of the substrate the film layer is applied is hydrophilic.

Aspect 15. The patterned film mask of aspect 13 or 14, wherein the film layer applied to the substrate is hydrophilic.

Aspect 16. The patterned film mask of aspects 1-12, further comprising a hydrophilic layer disposed on the surface of the base layer, wherein the plurality of through holes permeate through the hydrophilic layer and the base layer.

Aspect 17. The patterned film mask of aspect 16, wherein the substrate comprises a hydrophobic material or the surface of the substrate the film layer is applied is hydrophobic.

Aspect 18. The patterned film mask of aspect 16 or 17, wherein the film layer applied to the substrate is hydrophobic.

Aspect 19. The patterned film mask of the preceding aspects, further comprising an adhesive layer formed on the base layer, wherein the adhesive layer is configured to adhere the patterned film mask to the substrate and the plurality of through holes permeate through the adhesive layer and the base layer.

Aspect 20. The patterned film mask of aspect 19, wherein the adhesive layer comprises a silicone, acrylic or urethane based adhesive material.

Aspect 21. The patterned film mask of aspect 19 or 20, wherein the adhesive layer has the same surface wettability characteristics as the base layer.

Aspect 22. The patterned film mask of aspect 21, wherein the adhesive layer and the base layer are hydrophobic.

Aspect 23. The patterned film mask of aspect 21, wherein the adhesive layer and the base layer are hydrophilic.

Aspect 24. The process of fabricating a patterned film layer on a substrate, the process comprising: providing a patterned film mask, the patterned film mask comprising a base layer and a plurality of through holes permeating through the base layer, wherein the plurality of through holes defines a predetermined pattern for the patterned film layer applied to the substrate; positioning the patterned film mask over the substrate; depositing a film layer material on the substrate and into the plurality of through holes; and removing the patterned film mask from the substrate.

Aspect 25. The process of aspect 24, wherein the base layer and the substrate have opposing polarities and the film layer and the substrate have substantially similar polarities.

Aspect 26. The process of aspect 25, wherein the base layer is hydrophobic and the substrate and the film layer are hydrophilic.

Aspect 27. The process of aspect 25, wherein the base layer is hydrophilic and the substrate and the film layer are hydrophobic.

Aspect 28. The process of aspect 26, wherein the providing a patterned film mask comprises treating a surface of the base layer with a hydrophobic surface coating and forming the plurality of through holes permeating through the base layer and the hydrophobic surface coating.

Aspect 29. The process of aspect 27, wherein the providing a patterned film mask comprises treating a surface of the base layer with a hydrophilic surface coating and forming the plurality of through holes permeating through the base layer and the hydrophilic surface coating.

Aspect 30. The process of aspects 24-29, further comprising drying the film layer material prior to the removing the patterned film mask from the substrate.

Aspect 31. The process of aspects 24-30, wherein the process occurs at room temperature and at atmospheric pressure.

Aspect 32. The process of aspects 24-31, wherein the film layer material comprises silver, aluminum, graphene, carbon nanotubes, metal nanoparticles, poly(3,4-ethylenedioxythiophene) polystyrene sulfonate or mixture thereof.

Aspect 33. The process of aspects 24-32, wherein the depositing the film layer material includes spray coating the film layer material onto the substrate and into the through holes.

Aspect 34. The process of aspect 33, wherein the film layer material comprises silver or aluminum.

Aspect 35. The process of aspects 24-34, wherein the positioning the patterned film mask over the substrate further comprises attaching the patterned film mask to the substrate.

Aspect 36. The process of aspect 35, wherein the attaching the patterned film mask to the substrate further comprises adhering the patterned film mask to the substrate using an adhesive material.

Aspect 37. The process of aspect 36, wherein the adhesive material is a silicone, acrylic or urethane based adhesive material.

Aspect 38. The process of aspects 24-37, wherein the providing a patterned film mask further comprises applying an adhesive layer on the base layer prior to forming the plurality of through holes, wherein the plurality of through holes permeate through the adhesive layer and the base layer.

Aspect 39. The process of aspects 24-38, wherein the removing the patterned film mask comprises delaminating the patterned film mask from the substrate.

Aspect 40. The process of aspects 24-39, wherein the removing the patterned film mask from the substrate further comprises dissolving the patterned film mask in an aqueous solution.

Aspect 41. The process of aspect 40, wherein the base layer of the patterned film mask comprises a water soluble polymer.

Aspect 42. The process of aspect 41, wherein the water-soluble polymer comprises polyvinyl alcohol.

Aspect 43. The process of aspects 24-42, wherein the providing a film mask further comprises providing a base layer and laser scribing the plurality of through holes permeating through the base layer in the predetermined pattern.

Aspect 44. The process of aspects 24-42, wherein the providing a film mask further comprises providing a base layer and punching the plurality of through holes permeating through the base layer in the predetermined pattern.

Aspect 45. The process of aspects 24-44, wherein the patterned film layer is an electrode in an organic light-emitting diode.

Aspect 46. The process of aspects 24-45, wherein the patterned film layer is an insulating layer in an organic light-emitting diode.

Aspect 47. The process of aspects 24-46, wherein the patterned film layer is an organic emission layer in an organic light-emitting diode.

Aspect 48. The process of fabricating a patterned film layer on a substrate, the process comprising: (a) treating the substrate with a hydrophilic treatment; (b) providing a patterned film mask, the patterned film mask comprising a base layer and a plurality of through holes permeating through the base layer and defining a predetermined pattern for the patterned film layer, (c) treating the patterned film mask with a hydrophobic surface treatment; (d) adhering the patterned film mask to the substrate; (e) depositing a film layer on the substrate through the plurality of through holes, wherein the film layer material comprises a transparent conductive material dissolved in a hydrophilic solvent; and (f) removing the patterned film mask from the substrate.

Aspect 49. The process of aspect 48, wherein the patterned film mask is hydrophobic and the substrate and the film layer material are hydrophilic.

Aspect 50. A patterned film mask for applying a film layer to a substrate, the patterned film mask comprising: a base layer; and a plurality of through holes permeating through the base layer defining a predetermined pattern for the film layer, wherein the substrate and the film layer are hydrophilic and the base layer is hydrophobic.

What is claimed:

1. A patterned film mask for applying a film layer to a substrate, the patterned film mask comprising: a base layer; and a plurality of through holes permeating through the base layer defining a predetermined pattern for the film layer, wherein the film layer and the base layer have at least one different surface wettability characteristic and the substrate and the film layer have at least one surface wettability characteristic that is the same.

2. The patterned film mask of claim 1, wherein the base layer is hydrophobic and the substrate and the film layer are hydrophilic.

3. The patterned film mask of claim 1, wherein the plurality of through holes is formed by a laser scribing process or a punching process.

4. The patterned film mask of claim 1, wherein the film layer is an electrode, insulating layer or an organic emission layer in an organic light-emitting diode.

5. The patterned film mask of claim 1, wherein the base layer comprises a water-soluble polymeric material.

6. The patterned film mask of claim 1, further comprising a hydrophobic layer disposed on the surface of the base layer, wherein the plurality of through holes permeates through the hydrophobic layer and the base layer.

7. The patterned film mask of claim 1, further comprising an adhesive layer formed on the base layer, wherein the adhesive layer is configured to adhere the patterned film mask to the substrate and the plurality of through holes permeate through the adhesive layer and the base layer.

8. The patterned film mask of claim 7, wherein the adhesive layer has at least one of the same wettability characteristics as the base layer.

9. The patterned film mask of claim 7, wherein the adhesive layer and the base layer are hydrophobic.

10. The process of fabricating a patterned film layer on a substrate, the process comprising:
providing a patterned film mask, the patterned film mask comprising a base layer and a plurality of through holes permeating through the base layer and defining a predetermined pattern for the patterned film layer, wherein the film layer and the base layer have at least one different surface wettability characteristic and the substrate and the film layer have at least one surface wettability characteristic that is the same;
positioning the patterned film mask over the substrate;
depositing a film layer material on the substrate and into the plurality of through holes; and
removing the patterned film mask from the substrate.

11. The process of claim 10, wherein the base layer and the substrate have opposing polarities and the film layer and the substrate have substantially similar polarities.

12. The process of claim 10, wherein the providing a patterned film mask comprises treating a surface of the base layer with a hydrophobic surface coating and forming the plurality of through holes permeating through the base layer and the hydrophobic surface coating.

13. The process of claim 10, further comprising drying the film layer material prior to the removing the patterned film mask from the substrate.

14. The process of claim 10, wherein the process occurs at room temperature and at atmospheric pressure.

15. The process of claim 10, wherein the depositing the film layer material includes spray coating the film layer material onto the substrate and into the through holes.

16. The process of claim 10, wherein the film layer material comprises silver or aluminum.

17. The process of claim 10, wherein the providing a patterned film mask further comprises applying an adhesive layer on the base layer prior to forming the plurality of through holes, wherein the plurality of through holes permeate through the adhesive layer and the base layer and the positioning the patterned film mask over the substrate further comprises adhering the patterned film mask to the substrate.

18. The process of claim 10, wherein the providing a film mask further comprises providing a base layer and laser scribing the plurality of through holes permeating through the base layer in the predetermined pattern.

19. The process of claim 10, wherein the providing a film mask further comprises providing a base layer and punching the plurality of through holes permeating through the base layer in the predetermined pattern.

20. A patterned film mask for applying a film layer to a substrate, the patterned film mask comprising: a base layer; and a plurality of through holes permeating through the base layer defining a predetermined pattern for the film layer, wherein the substrate and the film layer are hydrophilic and the base layer is hydrophobic.
